(19) United States
(12) Patent Application Publication
(10) Pub. No.: US 2025/0254845 A1
(43) Pub. Date: Aug. 7, 2025

(54) CHARGING PILE

(71) Applicants: Futaijing Precision Electronics (Yantai) Co., Ltd., Yantai (CN); HON HAI PRECISION INDUSTRY CO., LTD., New Taipei (TW)

(72) Inventors: YI-LUN WEI, New Taipei (TW); SHENG-LI YEN, New Taipei (CN); YU-SHENG CHANG, New Taipei (CN); CHI-CHENG WEN, New Taipei (TW); CHIUNG-HSIANG WU, New Taipei (TW); CHIH-CHENG LEE, New Taipei (TW); YU-CHENG ZHANG, New Taipei (TW); CHEN-TING KAO, New Taipei (TW); CHEN CHAO, New Taipei (TW); CHUNG-WEI LU, New Taipei (TW)

(21) Appl. No.: 18/676,683

(22) Filed: May 29, 2024

(30) Foreign Application Priority Data
Feb. 1, 2024 (CN) 202420251818.X

(51) Int. Cl. H05K 7/20; B60L 53/31; H02J 7/00

(52) U.S. Cl. CPC H05K 7/20909; H02J 7/0042; B60L 53/31

(57) ABSTRACT

A charging pile is provided, comprising a shell, providing with an input control area, a power holding area and a power output area. The power output area defines a first channel, an end of the first channel is communicated with external environment. The input control area defines a second channel, heat generated by the power output module and the input control module is transmitted to the second channel. The power holding area defines a third channel, the second channel is communicated with the first channel and the third channel, the third channel is located on a side of the power module, cold air flows into the second channel through the first channel, brings out part of heat of the power output module and the input control module, and then flows out of the third channel.

### FIELD

The present disclosure relates to field of electrical equipment technology, particularly to a charging pile.

### BACKGROUND

With the continuous popularity of new energy vehicles, more and more cities have been provided with charging piles. The charging piles can quickly charge new energy vehicles. The charging piles can be fixed on the ground or walls, installed in public buildings and residential parking lots, or charging stations, and can charge various types of new energy vehicles according to different voltage levels. An input end of the charging pile is directly coupled to the alternating current power (AC power) grid, and an output end of the charging pile is provided with a charging plug for charging new energy vehicles.

Heat dissipation efficiency of current charging pile is low, and an interior of the charging pile is an enclosed space. When heat dissipation effect of the charging pile is poor, the temperature of an internal space in the charging pile may continue to rise, a service life and output power of the internal electrical components are affected, may even lead to shutdown of the charging pile. The charging pile has complex assembly method and high cost to assemble.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a schematic view of a charging pile in an embodiment of the present disclosure.

FIG. 2 illustrates a side view of the charging pile in FIG. 1.

FIG. 3 illustrates a schematic view of the charging pile without a power module, an input control module, and a power output module in FIG. 1.

FIG. 4 illustrates a current flow diagram of the charging pile in FIG. 1.

FIG. 5 illustrates a schematic view of a back structure of the charging pile in FIG. 1.

FIG. 6 illustrates an enlarged schematic view of VI in FIG. 3.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to”; it specifically indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein comprises any and all combinations of one or more of associated listed items.

Some embodiments of the present application are described in detail. In the case of no conflict, the following embodiments and the features in the embodiments can be combined with each other.

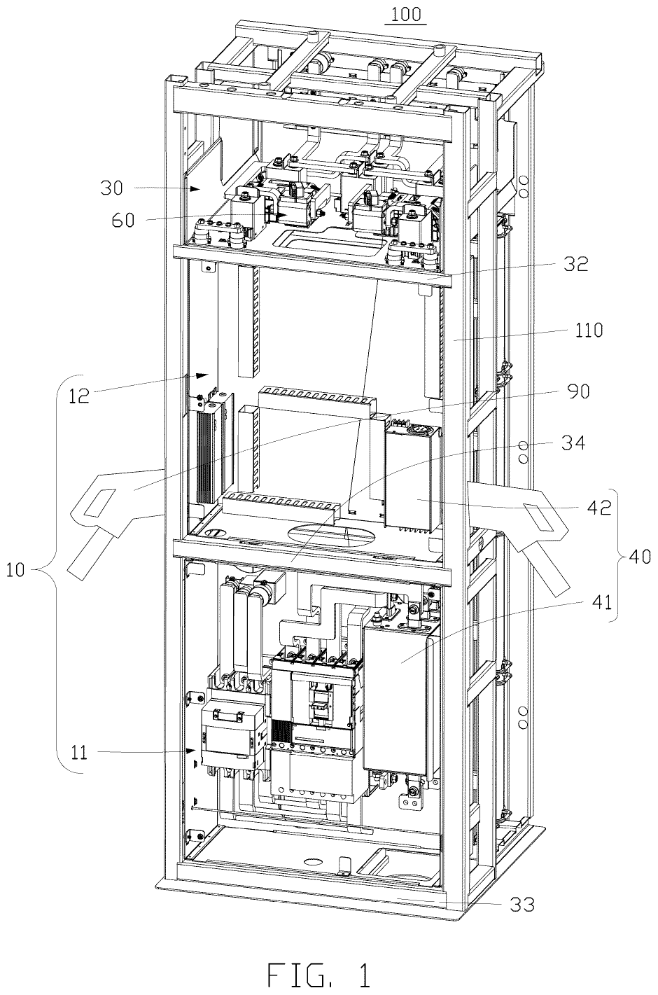

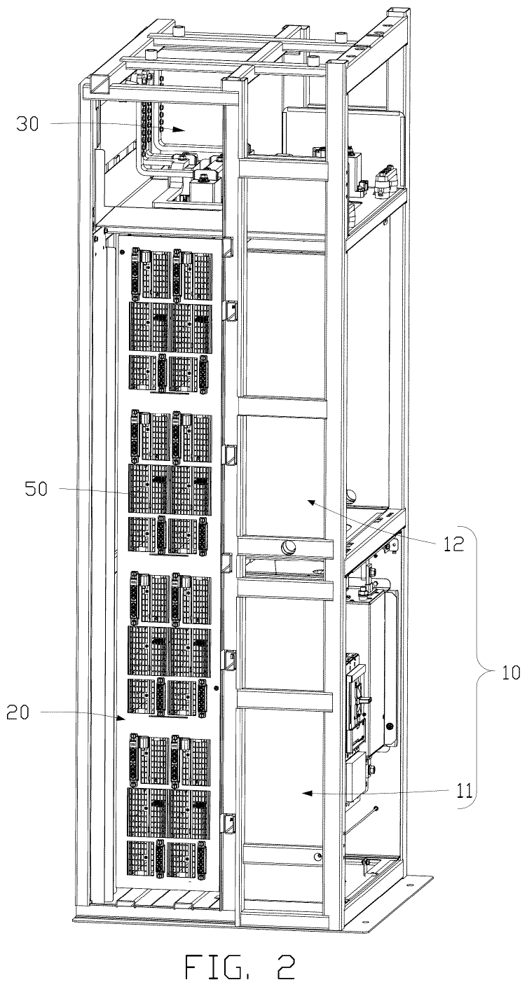

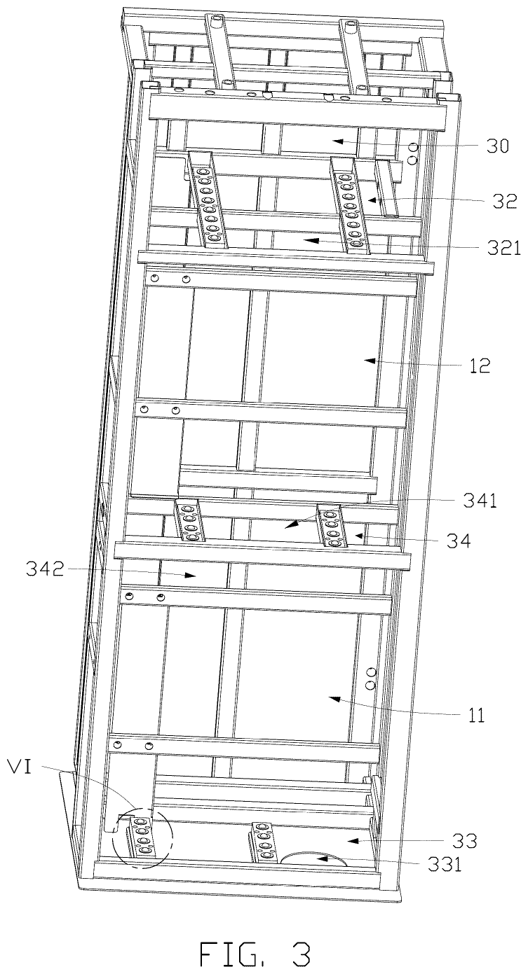

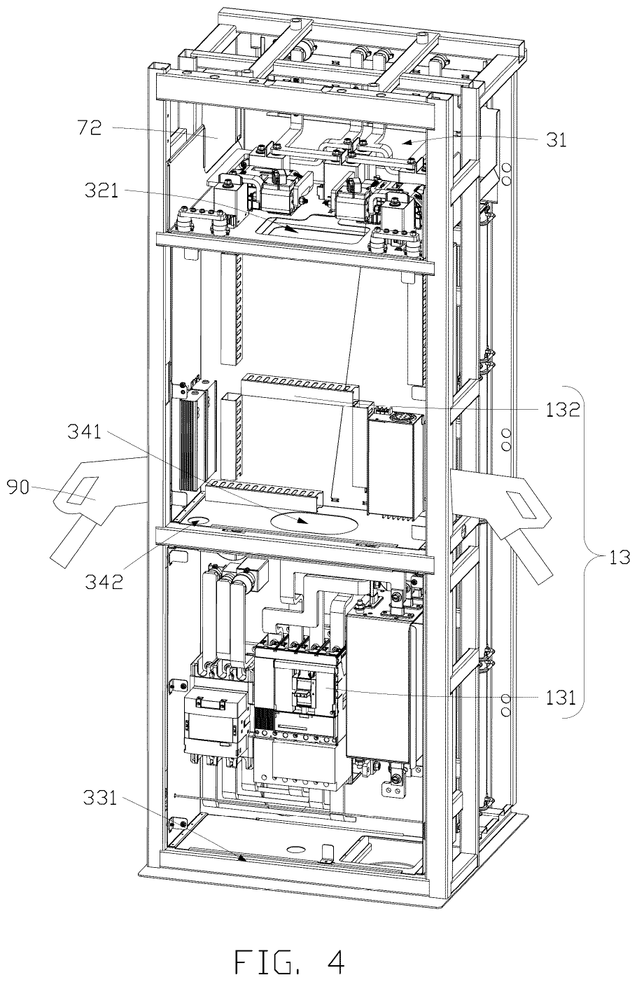

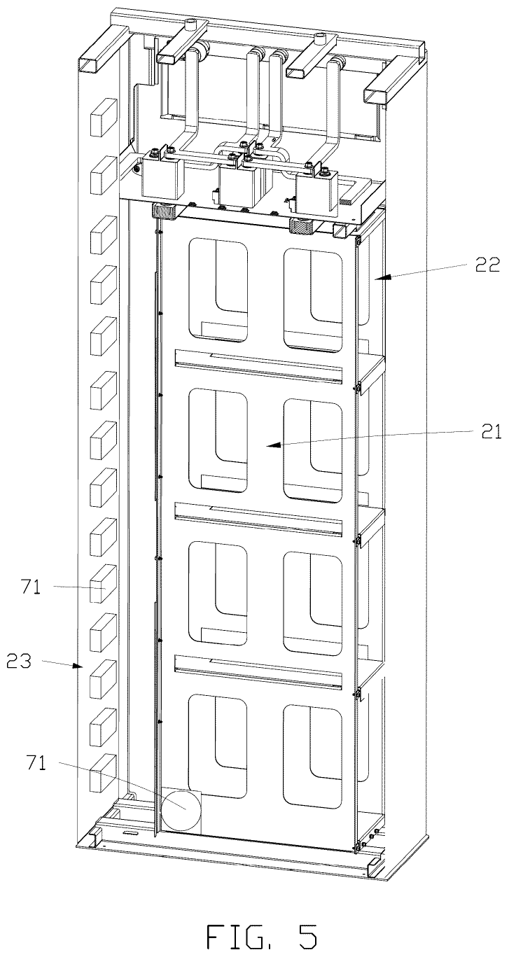

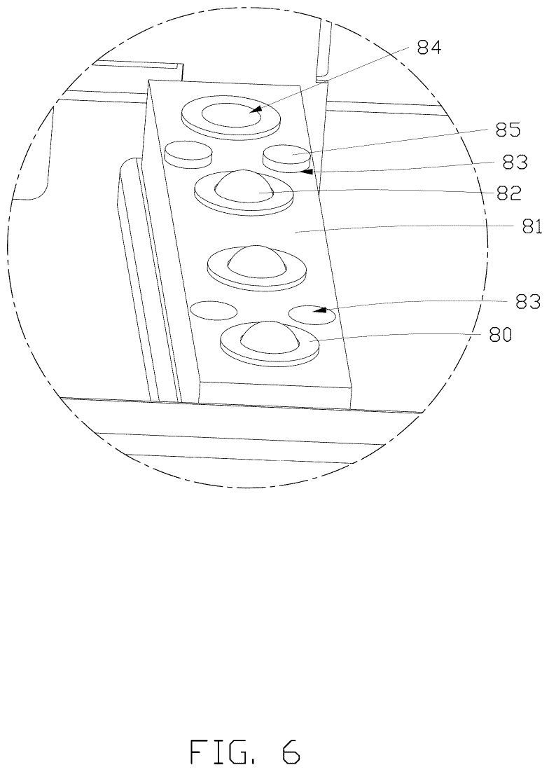

Referring to FIG. 1, FIG. 2, FIG. 3, FIG. 4, FIG. 5, and FIG. 6, one embodiment of the present application discloses a charging pile 100. The charging pile 100 can charge new energy vehicles.

Referring to FIG. 1, FIG. 2, FIG. 4, and FIG. 5, the charging pile 100 includes a shell 110. The shell 110 includes an input control area 10, a power holding area 20, and a power output area 30. The input control area 10 and the power holding area 20 are relatively arranged, the power output area 30 is arranged at an end of the power holding area 20. The charging pile 100 may also includes an input control module 40, a power module 50, and a power output module 60. The input control module 40, the power module 50 and the power output module 60 are arranged in the shell 110.

The input control area 10 is installed with the input control module 40, the power holding area 20 is installed with the power module 50, the power output area 30 is installed with the power output module 60. The input control module 40 is coupled to the power module 50, the power module 50 is coupled to the power output module 60. The power output area 30 defines a first channel 31, an end of the first channel 31 is communicated with external environment, the first channel 31 is located on a side of the power output module 60. The input control area 10 defines a second channel 13, heat generated by the power output module 60 and the input control module 40 is transmitted to the second channel 13, the second channel 13 is located on a side of the input control module 40. The power holding area 20 defines a third channel 21, the second channel 13 is communicated with the first channel 31 and the third channel 21, the third channel 21 is located on a side of the power module 50.

The cold air flows into the second channel 13 through the first channel 31, brings out part of heat of the power output module 60 and the input control module 40, and then flows out of the third channel 21. The input control module 40 is coupled to electric supply and is responsible for stably transmitting alternating current (AC) power obtained from the electric supply to the power module 50. The input control module 40 also controls the power of the charging pile 100 to be turned on or off. The power module 50 converts the AC power input from the input control module 40 to direct current power and transmits the direct current power to the power output module 60. The power output module 60 converts a voltage of the direct current power to voltages required by vehicles.

When the charging pile 100 is working, multiple modules installed in various areas of the shell 110 may generate a large amount of heat. In order to ensure that the charging pile 100 can continue to work normally, it is necessary to cool the internal area of the charging pile 100. In the embodiment, the shell 110 of the charging pile 100 is divided into three areas: the input control area 10, the power supply holding area 20, and the power output area 30. The second channel 13 is defined in the input control area 10, the third channel 21 is defined in the power holding area 20, and the first channel 31 is defined in the power output area 30. After the external cold air enters the first channel 31 to carry out heat generated by the power output module 60, and heat generated by the power output module 60 and the input control module 40 is then transmitted to the second channel 13, the second channel 13 can flow out of heat of the input control area 10. Heat transmitted from the first channel 31 to the second channel 13 and heat generated by the input control module 40 are jointly transmitted to the third channel 21. Finally, all heat can flow out of the third channel 21. The charging pile 100 is divided into multiple areas, and multiple channels are defined in multiple areas to bring out heat in multiple areas.

In one embodiment, referring to FIG. 4 and FIG. 5, the shell 110 defines an air inlet 22 and an exhaust outlet 23, the air inlet 22 and the exhaust outlet 23 are located on opposite sides of the power holding area 20, the air inlet 22 is communicated with the first channel 31, the second channel 13, the third channel 21 and the exhaust outlet 23. The cold air can enter the shell 110 from the air inlet 22, and the heat flowing from the first channel 31, the second channel 13 to the third channel 21 can flow to the outside world through the exhaust outlet 23.

In the embodiment, one side of the power holding area 20 provided with the exhaust outlet 23 further provides with an exhaust portion 71, the exhaust portion 71 is connected to a side of the shell 110 close to the power module 50, the exhaust portion 71 flows out heat in the power holding area 20 through the third channel 21. Under the wind of the exhaust portion 71, the heat from the first channel 31, the second channel 13 to the third channel 21 can be quickly discharged to the outside world, the heat cannot be accumulated in the third channel 21, the power module 50 can work properly.

Referring to FIG. 3 and FIG. 4, the shell 110 includes a first board 32 and a second board 33, the first board 32 is located between the power output area 30 and the input control area 10, the second board 33 is located at the input control area 10 away from the power output area 30. The first board 32 defines a first flow outlet 321, the second board 33 defines a second flow outlet 331, the first flow outlet 321 is communicated with the first channel 31 and the second channel 13, the second flow outlet 331 is communicated with the second channel 13 and the third channel 21. The heat generated by the power output module 60 in the power output area 30 can flow into the input control area 10 through the first flow outlet 321. The heat generated by the input control module 40 in the input control area 10 and the heat from the first channel 31 into the second channel 13 together flows into the power holding area 20 through the second flow outlet 331. Finally, all heat flows to the outside world through the third channel 21 in the power holding area 20.

In one embodiment, a side of the power output area 30 near the power output module 60 provides an air intake portion 72, the air intake portion 72 is connected to the shell 110. The exhaust portion 71 flows cold air on both sides of the power output area 30 into the first channel 31. The air intake portion 72 is arranged to increase the flow rate of cold air in the power output area 30, and the first channel 31 can quickly flow the heat generated by the power output module 60 into the second channel 13.

The shell 110 further includes a third board 34, the third board 34 is located in a middle of the input control area 10. The third board 34 defines a third flow outlet 341 and a fourth flow outlet 342, the third flow outlet 341 is spaced with the fourth flow outlet 342. The second channel 13 is divided into a first air duct 131 and a second air duct 132 by the third board 34, the second air duct 132 is communicated with the first air duct 131. The fourth flow outlet 342 is communicated with the first air duct 131, the second air duct 132, and the third channel 21.

In the embodiment, the third flow outlet 341 is located in the middle of the third board 34, the heat in the first air duct 131 can flow into the second air duct 132. The fourth flow outlet 342 is located at the edge of the third board 34, the cold air at the air inlet 22 and/or the exhaust outlet 23 of the power holding area 20 flows out of the second air duct 132.

In the embodiment, referring to FIG. 1, the input control area 10 is divided into a power input area 11 and a power control area 12 by the third board 34, the power input area 11 is installed with a power input module 41, the power control area 12 is installed with a power control module 42, the power input module 41 is coupled to the power control module 42, the power control module 42 is coupled to the power module 50.

Referring to FIG. 3 and FIG. 6, each of the first board 32, the second board 33 and the third board 34 is provided with a sliding portion 80, the power output module 60 is connected to the first board 32 through the sliding portion 80, the power input module 41 is connected to the second board 33 through the sliding portion 80, the power control module 42 is connected to the third board 34 through the sliding portion 80.

In the embodiment, the sliding portion 80 includes a fixing plate 81 and a roller 82. The fixing plate 81 is connected to the first board 32, the second board 33, and the third board 34, the fixing plate 81 defines a rolling groove 84, the roller 82 is placed in the rolling groove 84. The sliding portion 80 also includes a plurality of fasteners 85, the fixing plate 81 defines a plurality of fixing holes 83, the plurality of the fasteners 85 is correspondingly placed in the plurality of the fixing holes 83 to install the fixing plate 81 at the first board 32, the second board 33, and the third board 34.

The plurality of the fasteners 85 can be screws. For example, when the power input module 41 is installed to the power input area 11, one end of the power input module 41 can be placed at one end of the sliding portion 80 of the second board 33. Then the power input module 41 is pushed towards the direction of the power input area 11. Under the push of external force, the roller 82 can be rotated in the rolling groove 84. The rotating force of the roller 82 and external force together drive the power input module 41 to be installed in the power input area 11. Thus, assembly steps of the power input module 41 are simplified. Assembly steps of the power output module 60, the power control module 42 and the power module 50 are the same as the power input module 41.

In one embodiment, referring to FIG. 5, a side of the input control area 10 near the power holding area 20 provides an exhaust portion 71, the exhaust portion 71 is connected to the input control module 40, the exhaust portion 71 flows heat in the input control area 10 into the third channel 21. In the embodiment, the exhaust portion 71 is an exhaust fan. The exhaust assembly 71 is located on the side of the power input area 11 near the power holding area 20. Heat in the power input area 11 is quickly transmitted to the power holding area 20 under the drive of the exhaust portion 71, and then flows to the outside world out of the third channel 21.

In other embodiments, the air intake portion 72 and exhaust portion 71 can be both blowers, or the air intake portion 72 is a fan, the exhaust portion 71 is a blower.

In one embodiment, the charging pile 100 also includes a plurality of charging guns 90. The plurality of the charging guns 90 is retractably connected to the shell 110. The plurality of the charging guns 90 is arranged on opposite sides of the input control area 10, and the plurality of the charging gun 90 is coupled to the power output module 60. The power control module 42 can separately control the plurality of the charging guns 90 to turn on or turn off charging of vehicles.

On the one hand, the shell 110 of the charging pile 100 is divided into four areas: the power input area 11, the power control area 12, the power holding area 20 and the power output area 30. The power input module 41 is installed in the power input area 11, and the power control module 42 is installed in the power control area 12. The power module 50 is installed in the power holding area 20 and the power output module 60 is installed in power output area 30. The first air duct 131 is defined in the power input area 11, the second air duct 132 is defined in the power control area 12, the third channel 21 is defined in the power holding area 20 and the first channel 31 is defined in the power output area 30. The four modules generate heat in the four areas. After the external cold air enters the power output area 30 through the first channel 31, the heat flows from the second air duct 132 and the first air duct 131 to the power holding area 20, and finally flows out of the third channel 21 to reduce the temperature in the four areas.

On the other hand, the rollers 82 and the rolling groove 84 are provided on the first board 32, the second board 33, and the third board 34, so that when the power input module 41 and the power control module 42, the power module 50 and the power output module 60 are installed to the corresponding area, the charging pile 100 can be easily assembled under the external driving force and the rotating force of the sliding portion 80, the assembly complexity and assembly cost of the charging pile 100 are reduced.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A charging pile comprising:
a shell, providing with an input control area; a power holding area; and a power output area, wherein
the input control area and the power holding area are relatively arranged, the power output area is arranged at an end of the power holding area, an input control module is installed in the input control area, a power module is installed in the power holding area, a power output module is installed in the power output area, the input control module is coupled to the power module, the power module is coupled to the power output module,
the power output area defines a first channel, an end of the first channel is communicated with external environment, the first channel is located on a side of the power output module, the input control area defines a second channel, heat generated by the power output module and the input control module is transmitted to the second channel, the second channel is located on a side of the input control module, the power holding area defines a third channel, the second channel is communicated with the first channel and the third channel, the third channel is located on a side of the power module, cold air flows into the second channel through the first channel, brings out part of heat of the power output module and the input control module, and then flows out of the third channel.

2. The charging pile as claimed in claim 1, wherein a side of the power output area near the power output module comprises an air intake portion, the air intake portion is connected to the shell, the air intake portion flows cold air on both sides of the power output area into the first channel.

3. The charging pile as claimed in claim 1, wherein a side of the input control area near the power holding area comprises an exhaust portion, the exhaust portion is connected to the input control module, the exhaust portion flows heat in the input control area into the third channel.

4. The charging pile as claimed in claim 1, wherein the shell defines an air inlet and an exhaust outlet, the air inlet and the exhaust outlet are located on opposite sides of the power holding area, the air inlet is communicated with the first channel, the second channel, the third channel, and the exhaust outlet.

5. The charging pile as claimed in claim 4, wherein the shell comprises a first board and a second board, the first board is located between the power output area and the input control area, the second board is located at a side of the input control area away from the power output area, the first board defines a first flow outlet, the second board defines a second flow outlet, the first flow outlet is communicated with the first channel and the second channel, and the second flow outlet is communicated with the second channel and the third channel.

6. The charging pile as claimed in claim 5, wherein the shell further comprises a third board, the third board is located in a middle of the input control area, the third board defines a third flow outlet and a fourth flow outlet, the third flow outlet is spaced with the fourth flow outlet, the second channel is divided into a first air duct and a second air duct by the third board, the second air duct is communicated with the first channel, the first air duct is communicated with the third channel, the third flow outlet is communicated with the first air duct and the second air duct, and the fourth flow outlet is communicated with the first air duct, the second air duct, and the third channel.

7. The charging pile as claimed in claim 5, wherein the shell further comprises a third board, the third board is located in a middle of the input control area, the input control area is divided into a power input area and a power control area by the third board, the power input area is installed with a power input module, the power control area is installed with a power control module, the power input module is coupled to the power control module, the power control module is coupled to the power module.

8. The charging pile as claimed in claim 7, wherein each of the first board, the second board, and the third board is provided with a sliding portion, the power output module is connected to the first board through the sliding portion, the power input module is connected to the second board through the sliding portion, the power control module is connected to the third board through the sliding portion.

9. The charging pile as claimed in claim 8, wherein the sliding portion comprises a fixing plate and a roller, the fixing plate is connected to the first board, the second board, and the third board, the fixing plate defines a rolling groove, the roller is placed in the rolling groove.

10. The charging pile as claimed in claim 4, wherein one side of the power holding area provided with the exhaust outlet further provides with an exhaust portion, the exhaust portion is connected to a side of the shell closed to the power module, the exhaust portion flows out heat in the power holding area out of the third channel.

11. The charging pile as claimed in claim 9, wherein the sliding portion further comprises a plurality of fasteners, the fixing plate defines a plurality of fixing holes, the plurality of the fasteners is placed in the plurality of the fixing holes.

12. The charging pile as claimed in claim 1, further comprising a plurality of charging guns, wherein the plurality of the charging guns is retractably connected to the shell, the plurality of the charging guns is arranged on opposite sides of the input control area, the plurality of the charging guns is coupled to the power output module.
